(19) United States
(12) Patent Application Publication
(10) Pub. No.: US 2024/0361683 A1
(43) Pub. Date: Oct. 31, 2024

(54) MASK BLANK AND PHASE SHIFT MASK

(71) Applicant: HOYA CORPORATION, Tokyo (JP)

(72) Inventors: Hiroaki SHISHIDO, Tokyo (JP); Keishi AKIYAMA, Tokyo (JP); Yasutaka HORIGOME, Tokyo (JP)

(73) Assignee: HOYA CORPORATION, Tokyo (JP)

(21) Appl. No.: 18/560,659

(22) PCT Filed: Mar. 31, 2022
(86) PCT No.: PCT/JP2022/016682

§ 371 Date: Nov. 13, 2023

(30) Foreign Application Priority Data
Jun. 29, 2021 (JP) 2021-107975

(51) Int. Cl. G03F 1/32

(52) U.S. Cl. CPC G03F 1/32

(57) ABSTRACT

Provided is a mask blank comprising a phase shift film A mask blank comprises a phase shift film on a transparent substrate. The phase shift film is made of a material comprising a transition metal, silicon, and nitrogen. A ratio of the total content of nitrogen and oxygen to the content of the transition metal is 12 or more and 19 or less in an internal region, wherein the internal region excludes a neighboring region of the phase shift film at an interface with the transparent substrate and a surface layer region of the phase shift film which is located opposite the transparent substrate.

### CROSS-REFERENCE TO RELATED APPLICATIONS

This application is the National Stage of International Application No. PCT/JP2022/016682, filed Mar. 31, 2022, which claims priority to Japanese Patent Application No. 2021-107975, filed Jun. 29, 2021, and the contents of which is incorporated by reference.

### TECHNICAL FIELD

The present disclosure relates to a mask blank, a method of manufacturing a phase shift mask, and a method of manufacturing a semiconductor device.

### BACKGROUND ART

In general, in a semiconductor device manufacturing process, a fine pattern is formed using a photolithography method. Many transfer masks are usually used for forming the fine pattern. In order to miniaturize a pattern of a semiconductor device, it is necessary to miniaturize a mask pattern formed on a transfer mask and to shorten a wavelength of an exposure light source used in photolithography. In recent years, a wavelength of an exposure light source used for manufacturing a semiconductor device has been shortened from a KrF excimer laser (wavelength: 248 nm) to an ArF excimer laser (wavelength: 193 nm).

The type of transfer mask includes a halftone phase shift mask in addition to a conventional binary mask including a light-shielding film pattern made of a chromium-based material on a transparent substrate. As such a halftone phase shift mask, for example, Patent Document 1 discloses a mask in which a light semi-transmissive film including at least one layer of a thin film mainly made of nitrogen, a metal, and silicon is formed on a transparent substrate.

In addition, Patent Document 2 discloses a phase shift mask including an light semi-transmissive film on a transparent substrate in order to enhance resistance to exposure light of an ArF excimer laser (so-called ArF light resistance), in which the light semi-transmissive film is formed of an incomplete nitride film mainly containing a transition metal, silicon, and nitrogen, and a content ratio of the transition metal to the transition metal and the silicon in the semi-transmissive film is less than 9%.

### PRIOR ART DOCUMENTS

### Patent Documents

Patent Document 1: JP 2002-162726 A
Patent Document 2: WO 2011/125337 A

### SUMMARY OF DISCLOSURE

### Technical Problem

It is already known that a phase shift film made of a material containing silicon and nitrogen with a reduced content ratio of a transition metal as disclosed in Patent Document 2 has high ArF light resistance. However, when EB defect correction is performed on a black defect portion found in a pattern of such a phase shift film, it has been found that the following problem occurs.

First, when the black defect portion of the phase shift film in which the content ratio of the transition metal is controlled to be small is removed by EB defect correction, a surface of the transparent substrate in a region where the black defect was present is largely roughened (surface roughness is significantly deteriorated). When the surface roughness of the substrate is significantly deteriorated, a decrease in transmittance of ArF exposure light, irregular reflection, and the like are likely to occur, and such a phase shift mask causes a significant decrease in transfer accuracy when the phase shift mask is disposed on a mask stage of an exposure apparatus to be used for exposure transfer.

In addition, when the black defect portion of the phase shift film in which a content ratio of nitrogen and oxygen is controlled to be small is removed by EB defect correction, there is a possibility that a transfer pattern formed on the phase shift film present around the black defect portion is etched from a side wall (This phenomenon is referred to as spontaneous etching.). When spontaneous etching occurs, the width of the transfer pattern becomes significantly thinner than that before EB defect correction. When a transfer pattern has a thin width before EB defect correction, dropping or disappearance of the pattern may occur. Such a phase shift mask including a pattern of a phase shift film in which spontaneous etching is likely to occur causes a significant decrease in transfer accuracy when the phase shift mask is disposed on a mask stage of an exposure apparatus to be used for exposure transfer.

The present disclosure has been made in order to solve the above conventional problems, and an aspect of the present disclosure is to provide a mask blank including a phase shift film that satisfies required light resistance to exposure light of an ArF excimer laser and enables easy EB defect correction with practically high accuracy. Another aspect of the present disclosure is to provide a method of manufacturing a phase shift mask using this mask blank. Still another aspect of the present disclosure is to provide a method of manufacturing a semiconductor device using such a phase shift mask.

### Solution to Problem

In order to solve the above problems, the present disclosure has the following configurations.

### (Configuration 1)

A mask blank comprising a phase shift film on a transparent substrate, in which
the phase shift film is made of a material containing a transition metal, silicon, and nitrogen, and
a ratio of a total content of nitrogen and oxygen to a content of the transition metal is 12 or more and 19 or less in an internal region, wherein the internal region excludes a neighboring region of the phase shift film at an interface with the transparent substrate and a surface layer region of the phase shift film which is located opposite the transparent substrate.

### (Configuration 2)

The mask blank according to configuration 1, in which the phase shift film has a total content of the transition metal, silicon, nitrogen, and oxygen of 97 atom % or more.

### (Configuration 3)

The mask blank according to configuration 1 or 2, in which the surface layer region is a region extending 5 nm in a depth direction from a surface of the phase shift film which is opposite to the transparent substrate to the transparent substrate.

### (Configuration 4)

The mask blank according to any one of configurations 1 to 3, in which the neighboring region is a region extending 5 nm in a depth direction from the interface with the transparent substrate to the surface layer region.

### (Configuration 5)

The mask blank according to any one of configurations 1 to 4, in which the surface layer region has a larger oxygen content than the internal region.

### (Configuration 6)

The mask blank according to any one of configurations 1 to 5, in which a ratio of a content of oxygen to a content of the transition metal in the internal region is less than 5.0.

### (Configuration 7)

The mask blank according to any one of the configurations 1 to 6, in which a ratio of a content of the transition metal to a total content of the transition metal and silicon in the internal region is 0.04 or more and 0.07 or less.

### (Configuration 8)

The mask blank according to any one of configurations 1 to 7, in which
the transition metal is molybdenum, and
when a Mo3d narrow spectrum in the internal region is acquired by performing analysis by X-ray photoelectron spectroscopy on the internal region, a ratio of a maximum peak in a range where binding energy of the Mo3d narrow spectrum is 226 eV or more and 229 eV or less to a maximum peak in a range where the binding energy of the Mo3d narrow spectrum is 230 eV or more and 233 eV or less is less than 1.2.

### (Configuration 9)

The mask blank according to any one of configurations 1 to 8, in which the phase shift film comprises a function of transmitting exposure light of an ArF excimer laser with a transmittance of 1% or more, and a function of generating a phase difference of 150 degrees or more and 210 degrees or less between the exposure light that has passed through the phase shift film and the exposure light that has passed through air by the same distance as a thickness of the phase shift film.

### (Configuration 10)

The mask blank according to any one of configurations 1 to 9, comprising a light-shielding film on the phase shift film.

### (Configuration 11)

A method of manufacturing a phase shift mask using the mask blank according to any one of configurations 1 to 10, the method comprising forming a transfer pattern on the phase shift film by dry etching.

### (Configuration 12)

A method of manufacturing a semiconductor device, the method comprising transferring, by exposure, the transfer pattern onto a resist film on a semiconductor substrate using a phase shift mask manufactured by the method of manufacturing a phase shift mask according to configuration 11.

### Advantageous Effects of Disclosure

A mask blank of the present disclosure is a mask blank including a phase shift film on a transparent substrate, characterized in that the phase shift film is made of a material containing a transition metal, silicon, and nitrogen, and a ratio of the total content of nitrogen and oxygen to the content of the transition metal is 12 or more and 19 or less in an internal region, wherein the internal region excludes a neighboring region of the phase shift film at an interface with the transparent substrate and a surface layer region of the phase shift film which is located opposite the transparent substrate. By using the mask blank having such a structure, required light resistance to exposure light of an ArF excimer laser can be satisfied, and EB defect correction can be easily performed with practically high accuracy.

### BRIEF DESCRIPTION OF DRAWINGS

FIG. 1 is a cross-sectional view illustrating a configuration of a mask blank according to an embodiment of the present disclosure.

FIGS. 2A-2G are schematic cross-sectional views illustrating a phase shift mask manufacturing process in the embodiment of the present disclosure.

FIG. 3 is a graph illustrating results of X-ray photoelectron spectroscopy on phase shift films of Examples 1 and 2 and Comparative Example 1 of the present disclosure.

### DESCRIPTION OF EMBODIMENTS

Hereinafter, each embodiment of the present disclosure will be described.

### [Mask Blank and Manufacture Thereof]

The present inventors have intensively conducted studies on a phase shift film made of a material containing a transition metal, silicon, and nitrogen, in which the phase shift film has high light resistance to exposure light of an ArF excimer laser (ArF exposure light) (ArF light resistance) and enables easy EB defect correction.

The phase shift film needs to have both a function of transmitting ArF exposure light with a predetermined transmittance and a function of generating a predetermined phase difference between the exposure light that has passed through the phase shift film and the exposure light that has passed through air by the same distance as the thickness of the phase shift film.

In EB defect correction of the phase shift film, three elements of a correction rate of the phase shift film, a correction rate difference between the phase shift film and the substrate, and detection accuracy of a correction end point are practically important in performing EB defect correction with high accuracy. In addition, these characteristics need to be satisfied without impairing requirements for generating the above-described transmittance and phase difference required for the phase shift film. Therefore, in order to favorably perform EB defect correction, a content ratio of the transition metal in the phase shift film is preferably increased.

Meanwhile, it is preferable to reduce the content ratio of the transition metal in the phase shift film in order to suppress generation of an altered layer containing the transition metal due to irradiation with ArF exposure light from a viewpoint of enhancing ArF light resistance.

Therefore, the present inventors have attempted to achieve both required ArF light resistance and easiness of EB defect correction by adjusting a ratio between the transition metal and silicon in the phase shift film on the premise of securing the above-described function required for the phase shift film.

However, it has been found that it is difficult to obtain a phase shift film capable of achieving both required ArF light resistance and easiness of EB defect correction even when the ratio between the transition metal and silicon in the phase shift film is adjusted.

Therefore, the present inventors have changed the idea and have focused not on the ratio between the transition metal and silicon but on a relationship between the transition metal, and nitrogen and oxygen contained in the phase shift film. Oxygen is not an essential element in the phase shift film, but has a non-negligible influence on ArF light resistance and EB defect correction.

On the basis of this viewpoint, the present inventors first formed a plurality of phase shift films on a plurality of transparent substrates by a sputtering method under different film forming conditions. Then, each of the phase shift films was analyzed by X-ray photoelectron spectroscopy to obtain a composition thereof. Furthermore, a relationship between the composition of each of the phase shift films, and ArF light resistance and EB defect correction was studied. As a result of intensive studies, it has been found that when a ratio of the total content of nitrogen and oxygen to the content of the transition metal in the internal region of the phase shift film satisfies a range of 12 or more and 19 or less, required light resistance to exposure light of an ArF excimer laser is satisfied, and EB defect correction can be easily performed with practically high accuracy. Here, the internal region of the phase shift film is a region in which the composition is stable in the phase shift film, and the internal region excludes a neighboring region which is located adjacent to an interface between the phase shift film and the transparent substrate and a surface layer region of the phase shift film which is located opposite the transparent substrate.

The present disclosure has been made as a result of intensive studies as described above.

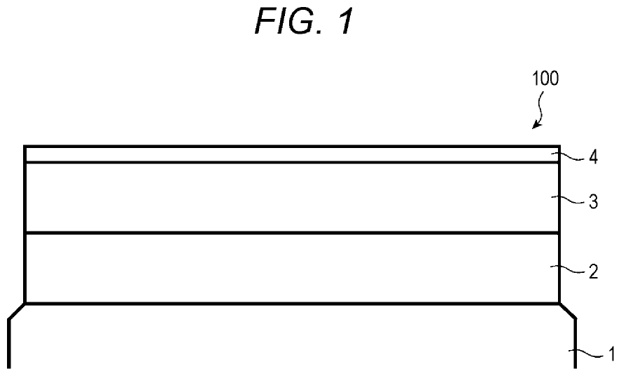

Next, an overall configuration of a mask blank will be described with reference to FIG. 1.

FIG. 1 is a cross-sectional view illustrating a configuration of a mask blank 100 according to the embodiment of the present disclosure. The mask blank 100 illustrated in FIG. 1 has a structure in which a phase shift film 2, a light-shielding film 3, and a hard mask film 4 are layered in this order on a transparent substrate 1.

The transparent substrate 1 can be made of synthetic quartz glass, quartz glass, aluminosilicate glass, soda lime glass, low thermal expansion glass (SiO₂—TiO₂ glass or the like), or the like. Among these, synthetic quartz glass is particularly preferable as a material for forming the transparent substrate of the mask blank because of having a high transmittance to ArF exposure light and sufficient rigidity that hardly causes deformation.

The phase shift film 2 is preferably formed in contact with a surface of the transparent substrate 1. This is because, at the time of EB defect correction, it is preferable that a film (for example, a film of a chromium-based material) is not formed between the transparent substrate 1 and the phase shift film 2, the film being made of a material to which EB defect correction is difficult to apply.

In order to effectively exhibit a phase shift effect, the phase shift film 2 has a transmittance of preferably 1% or more, more preferably 2% or more to ArF exposure light. In addition, the phase shift film 2 is preferably adjusted to have the transmittance to ArF exposure light of 20% or less. The transmittance is more preferably 15% or less, and still more preferably 11% or less.

In order to obtain an appropriate phase shift effect, the phase shift film 2 is required to have a function of generating a predetermined phase difference between ArF exposure light that passes through the phase shift film 2 and light that has passed through air by the same distance as the thickness of the phase shift film 2. In addition, the phase difference is preferably adjusted so as to fall within a range of 150 degrees or more and 210 degrees or less. A lower limit value of the phase difference in the phase shift film 2 is more preferably 160 degrees or more, and still more preferably 170 degrees or more. Meanwhile, an upper limit value of the phase difference in the phase shift film 2 is more preferably 190 degrees or less. This is for reducing an influence of an increase in phase difference due to minute etching of the transparent substrate 1 during dry etching when a pattern is formed on the phase shift film 2. In addition, this is also because in recent years, as a method of irradiating a phase shift mask with ArF exposure light by an exposure apparatus, a method of making ArF exposure light incident from a direction inclined at a predetermined angle with respect to a direction perpendicular to a film surface of the phase shift film 2 has been used more often.

The phase shift film 2 is made of a material containing a transition metal, silicon, and nitrogen. The transition metal contained in the phase shift film 2 is, for example, any one metal of molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), niobium (Nb), palladium (Pd), and the like, or an alloy of these metals. The phase shift film 2 may contain any metalloid element in addition to silicon. Among the metalloid elements, inclusion of one or more elements selected from boron, germanium, antimony, and tellurium is preferable because enhancement of conductivity of silicon used as a sputtering target can be expected.

The phase shift film 2 may contain any nonmetallic element in addition to nitrogen. Here, the nonmetallic element in the present disclosure refers to those including a nonmetallic element in a narrow sense (nitrogen, carbon, oxygen, phosphorus, sulfur, or selenium), a halogen, and a noble gas. Among these nonmetallic elements, one or more elements selected from carbon, fluorine, and hydrogen are preferably contained. In the phase shift film 2 excluding a surface layer region described later, the content of oxygen is preferably suppressed to 20 atom % or less, and more preferably 18 atom % or less. When the oxygen content in the phase shift film 2 is large, a correction rate at the time of EB defect correction is significantly decreased.

The phase shift film 2 may contain a noble gas. The noble gas is an element that can increase a film forming speed and improve productivity by being present in a film forming chamber when the phase shift film 2 is formed by reactive sputtering. The noble gas is turned into plasma and collides with a target to cause a target constituent element to jump out from the target, and thereby the phase shift film 2 is formed on the transparent substrate 1 while taking in a reactive gas halfway. The noble gas in the film forming chamber is slightly taken in after the target constituent element jumps out from the target and before the target constituent element is attached to the transparent substrate 1. Preferable examples of the noble gas required for this reactive sputtering include argon, krypton, and xenon. In addition, helium or neon having a small atomic weight can be positively taken into a thin film in order to reduce a film stress of the phase shift film 2.

In the phase shift film 2, the total content of the transition metal, silicon, nitrogen, and oxygen is preferably 97 atom % or more, more preferably 98 atom % or more, and still more preferably 99 atom % or more. In order to exclude an element that disadvantageously acts on the phase shift mask from the phase shift film 2, the phase shift film 2 is preferably formed so as to consists of the transition metal, silicon, nitrogen, and oxygen except for an element that is inevitably introduced or an element that is intentionally introduced (a metalloid element and a nonmetallic element).

The phase shift film 2 preferably has a film thickness of at least 90 nm or less. This is because a bias (Electromagnetic Field Bias (EMF bias)) relating to an electromagnetic field effect can be reduced by thinning the film. Therefore, the thickness of the phase shift film 2 is more preferably 85 nm or less, and still more preferably 80 nm or less. In addition, by setting the film thickness of the phase shift film to that of such a thin film, defects due to pattern collapse on a mask are suppressed, and a yield of the phase shift mask is improved. Meanwhile, the phase shift film 2 preferably has a thickness of 40 nm or more. When the thickness of the phase shift film 2 is less than 40 nm, there is a possibility that a predetermined transmittance and a predetermined phase difference required for the phase shift film cannot be obtained.

In the phase shift film 2, a refractive index n to ArF exposure light (hereinafter, simply referred to as a refractive index n) at an average value in the whole (an average value in the whole of a substrate neighboring region, an internal region, and a surface layer region described later) is preferably 1.9 or more, and more preferably 2.0 or more. In addition, the refractive index n of the phase shift film is preferably 3.1 or less, and more preferably 2.8 or less. In addition, in the phase shift film 2, an extinction coefficient k to ArF exposure light at an average value in the whole (hereinafter, simply referred to as an extinction coefficient k) is preferably 1.2 or less, and more preferably 1.0 or less. In addition, in the phase shift film 2, the extinction coefficient k at an average value in the whole is preferably 0.1 or more, and more preferably 0.2 or more. This is because it is difficult to achieve a predetermined phase difference and a predetermined transmittance to ArF exposure light, which are optical characteristics required for the phase shift film 2, unless the refractive index and the extinction coefficient fall within the ranges of the refractive index n and the extinction coefficient k described above.

The refractive index n and the extinction coefficient k of the thin film including the phase shift film 2 are not determined only by a composition of the thin film. A film density, a crystal state, and the like of the thin film are also factors that affect the refractive index n and the extinction coefficient k. Therefore, various conditions when the thin film is formed by reactive sputtering are adjusted, and the thin film is formed so as to have a desired refractive index n and a desired extinction coefficient k. In order to make the phase shift film 2 fall within the above ranges of the refractive index n and the extinction coefficient k, it is effective to adjust a ratio of a mixed gas of a noble gas and a reactive gas (oxygen gas, nitrogen gas, or the like) at the time of film formation by reactive sputtering, but an effective condition is not limited thereto. There are a variety of effective conditions such as a pressure in a film forming chamber when the film is formed by reactive sputtering, power applied to a sputtering target, and a positional relationship such as a distance between the target and the transparent substrate 1. In addition, these film forming conditions are unique to a film forming apparatus, and are appropriately adjusted such that the phase shift film 2 to be formed has a desired refractive index n and a desired extinction coefficient k.

The inside of the phase shift film 2 is divided into three regions of a substrate neighboring region (neighboring region), an internal region, and a surface layer region in this order from the transparent substrate 1 side. The substrate neighboring region (neighboring region) extends 5 nm in a depth direction from an interface between the phase shift film 2 and the transparent substrate 1 to a surface located opposite the transparent substrate 1 (that is, the surface layer region). When the substrate neighboring region is analyzed by X-ray photoelectron spectroscopy, the substrate neighboring region is easily affected by the transparent substrate 1 present thereunder. In addition, accuracy of a maximum peak of a photoelectron intensity in each of the acquired narrow spectra of Si2p, Mo3d, N1s, O1s, and the like in the substrate neighboring region is low. That is, accuracy of a composition of the substrate neighboring region acquired from the analysis result by X-ray photoelectron spectroscopy is low.

The surface layer region extends 5 nm in the depth direction from a surface located opposite the transparent substrate 1 to the transparent substrate 1. Since the surface layer region contains oxygen taken in from a surface of the phase shift film 2, the surface layer region has a structure in which a composition gradient of the oxygen content is observed in a thickness direction of the film (a structure having a composition gradient in which the oxygen content in the film increases as a distance from the transparent substrate 1 increases). That is, the oxygen content in the surface layer region is larger than that in the internal region.

The internal region is a region of the phase shift film 2 excluding the substrate neighboring region and the surface layer region. A maximum peak of a photoelectron intensity of each of the narrow spectra acquired by analyzing the internal region by X-ray photoelectron spectroscopy is a value hardly affected by the transparent substrate 1 or surface layer oxidation. Therefore, it can be said that the maximum peak of the photoelectron intensity of each of the narrow spectra in this internal region is a value reflecting easiness of excitation (work function) of the material containing the transition metal, silicon, and nitrogen constituting the internal region with respect to irradiation with an X-ray or an electron beam.

A ratio [(N+O)/X ratio] (X represents a transition metal. The same applies hereinafter) of the total content of nitrogen and oxygen to the content of the transition metal in the internal region of the phase shift film 2 is 12 or more and 19 or less. When the (N+O)/X ratio in the internal region is less than 12, it is difficult to satisfy required ArF light resistance. In addition, when the (N+O)/X ratio in the internal region exceeds 19, it is difficult to satisfy required easiness of EB defect correction. The (N+O)/X ratio in the internal region is more preferably 13 or more, and still more preferably 14 or more.

The content of nitrogen in the internal region of the phase shift film is preferably 30 atom % or more. In addition, the content of nitrogen in the internal region of the phase shift film is preferably 50 atom % or less. The internal region of the phase shift film 2 does not have to contain oxygen (An O1s narrow spectrum acquired by analysis by X-ray photoelectron spectroscopy is equal to or less than a lower limit value.).

In the internal region of the phase shift film 2, a ratio [O/X ratio] of the oxygen content to the transition metal content in the internal region is preferably less than 5.0, and more preferably 4.9 or less. This is because when the O/X ratio in the internal region is 5.0 or more, easiness of EB defect correction tends to decrease.

In addition, in the internal region of the phase shift film 2, a ratio [X/(X+Si) ratio] of the content of the transition metal to the total content of the transition metal and silicon is preferably 0.04 or more and 0.07 or less, and more preferably 0.050 or more and 0.065 or less. This is because when the X/(X+Si) ratio is more than 0.07, ArF light resistance tends to decrease, and when the X/(X+Si) ratio is less than 0.04, easiness of EB defect correction tends to decrease.

As the transition metal contained in the phase shift film 2, molybdenum is particularly preferable from a viewpoint of availability of a high-quality target or the like.

The present inventors analyzed the internal region of the phase shift film 2 containing molybdenum as the transition metal by X-ray photoelectron spectroscopy to acquire a Mo3d narrow spectrum in the internal region. Then, as a result of studying a relationship between the acquired Mo3d narrow spectrum and ArF light resistance, it has been found that a ratio [Ip1/Ip2 ratio] of a maximum peak [Ip1] in a range where binding energy of the Mo3d narrow spectrum is 226 eV or more and 229 eV or less to a maximum peak [Ip2] in a range where the binding energy of the Mo3d narrow spectrum is 230 eV or more and 233 eV or less is advantageously less than 1.2 in order to enhance ArF light resistance.

The present inventors presume a reason for this as follows. The Mo3d narrow spectrum is divided into two peaks of 3d_{5/2} and 3d₃/2, and peak positions of the two spectra (values of binding energy) change depending on a chemical binding state of Mo. It has been found that the phase shift film 2 containing molybdenum, nitrogen, silicon, (and oxygen) has a maximum peak [Ip2] in a range where the binding energy is a higher value of 230 eV or more and 233 eV or less, and a maximum peak [Ip1] in a range where the binding energy is a lower value of 226 eV or more and 229 eV or less. It can be said when a ratio between these maximum peaks [Ip1/Ip2 ratio] is less than 1.2, the number of Mo atoms having higher binding energy among the entire Mo atoms in the phase shift film 2 is larger than that in a case where the ratio is 1.2 or more. That is, it is presumed when the ratio between these maximum peaks [Ip1/Ip2 ratio] is less than 1.2, Mo is less likely to move as compared with a case where the ratio is 1.2 or more, and it is presumed that ArF light resistance is thus improved. Note that this presumption does not limit the scope of rights of the present disclosure at all.

As described above, in the phase shift film 2, when a Mo3d narrow spectrum in the internal region is acquired by performing analysis by X-ray photoelectron spectroscopy on the internal region, a ratio [Ip1/Ip2 ratio] of a maximum peak [Ip1] in a range where binding energy of the Mo3d narrow spectrum is 226 eV or more and 229 eV or less to a maximum peak [Ip2] in a range where the binding energy of the Mo3d narrow spectrum is 230 eV or more and 233 eV or less is preferably less than 1.2, and more preferably 1.19 or less.

The phase shift film 2 is formed by sputtering, and it is possible to apply any sputtering such as DC sputtering, RF sputtering, or ion beam sputtering. In a case of using a target having low conductivity, it is preferable to apply RF sputtering or ion beam sputtering, and in consideration of a film forming rate, it is more preferable to apply RF sputtering.

The surface layer region of the phase shift film 2 is desirably a layer (hereinafter, also referred to as a surface oxidized layer) having a larger oxygen content than the internal region of the phase shift film 2. The phase shift film 2 having a layer having a high oxygen content at a surface layer has high resistance to a cleaning liquid used in a cleaning step in a mask manufacturing process or mask cleaning performed when the phase shift mask is repeatedly used. As a method of forming the surface oxidized layer of the phase shift film 2, various oxidation treatments can be applied. Examples of the oxidation treatments include a heat treatment in a gas containing oxygen, such as in the atmosphere, a light irradiation treatment by a flash lamp or the like in a gas containing oxygen, and a treatment of bringing ozone or oxygen plasma into contact with an uppermost layer. In particular, it is preferable to form the surface oxidized layer in the phase shift film 2 using a heating treatment or a light irradiation treatment by a flash lamp or the like which can simultaneously reduce a film stress of the phase shift film 2. The surface oxidized layer of the phase shift film 2 has a thickness of preferably 1 nm or more, more preferably 1.5 nm or more. In addition, the surface oxidized layer of the phase shift film 2 has a thickness of preferably 5 nm or less, more preferably 3 nm or less.

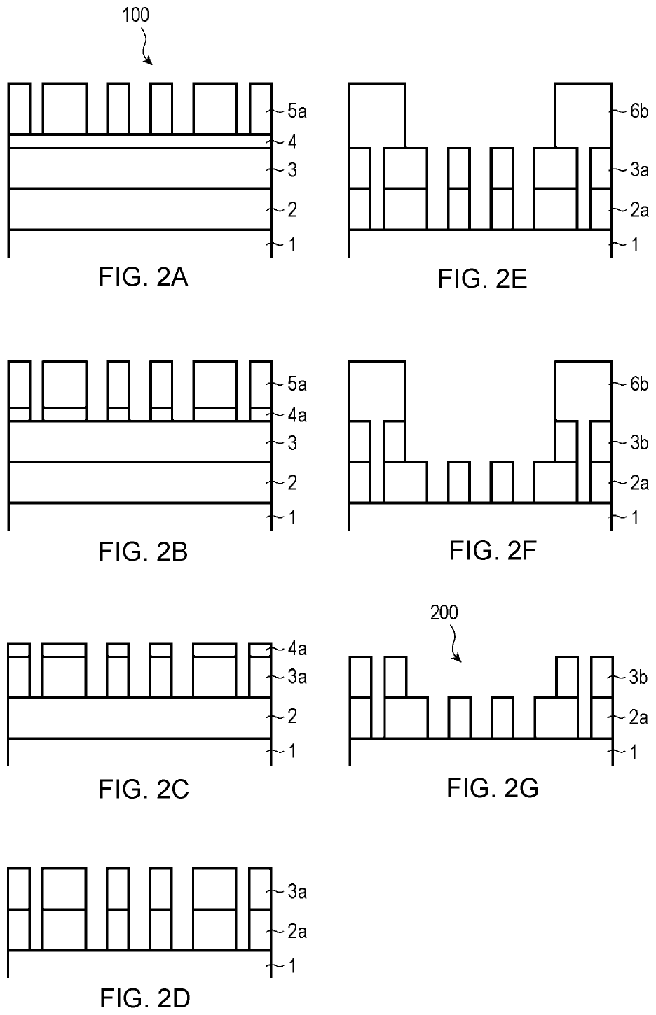

The mask blank 100 includes the light-shielding film 3 on the phase shift film 2. In general, in a binary transfer mask, an outer peripheral region of a region in which a transfer pattern is formed (transfer pattern forming region) is required to secure an optical density (OD) of a predetermined value or more such that a resist film on a semiconductor wafer is not affected by exposure light that has passed through the outer peripheral region when exposure transfer is performed onto the resist film using an exposure apparatus. The same applies to a phase shift mask. Usually, in the outer peripheral region of the transfer mask including the phase shift mask, the OD is expected to be 3.0 or more, and at least 2.8 or more is required. The phase shift film 2 has a function of transmitting exposure light with a predetermined transmittance, and it is difficult to secure an optical density of a predetermined value required for the outer peripheral region only with the phase shift film 2. Therefore, at a stage of manufacturing the mask blank 100, the light-shielding film 3 needs to be layered on the phase shift film 2 for securing an optical density which would otherwise be insufficient. With such a configuration of the mask blank 100, it is possible to manufacture the phase shift mask 200 in which an optical density of a predetermined value is secured in the outer peripheral region by removing the light-shielding film 3 in a region in which a phase shift effect is used (basically, a transfer pattern forming region) in a course of manufacturing the phase shift mask 200 (refer to FIGS. 2A-2G).

Note that when an intensity of light incident on a target film is denoted by I₀ and an intensity of light that has passed through the film is denoted by I, the optical density OD is defined by

$$OD = - {log}_{10} ( I / {I}_{0} ) .$$

Either a single-layer structure or a stack of two or more layers is applicable to the light-shielding film 3. In addition, the light-shielding film having a single-layer structure and each layer of the light-shielding film having a stack of two or more layers may each have substantially the same composition in a thickness direction of the film or the layer, or may have a composition gradient in the thickness direction of the layer.

The mask blank 100 illustrated in FIG. 1 has a configuration in which the light-shielding film 3 is layered on the phase shift film 2 without another film interposed therebetween. In the light-shielding film 3 in this configuration, it is necessary to apply a material having sufficient etching selectivity to an etching gas used for forming a pattern on the phase shift film 2.

The light-shielding film 3 in this case is preferably made of a chromium-containing material. The chromium-containing material for forming the light-shielding film 3 is, for example, in addition to a chromium metal, a material containing chromium (Cr) and one or more elements selected from oxygen (O), nitrogen (N), carbon (C), boron (B), and fluorine (F). In general, a chromium-based material is etched with a mixed gas of a chlorine-based gas and oxygen gas, but a chromium metal has an etching rate that is not so high for this etching gas. In order to increase the etching rate for the etching gas of the mixed gas of a chlorine-based gas and oxygen gas, the material for forming the light-shielding film 3 is preferably a material containing chromium and one or more elements selected from oxygen, nitrogen, carbon, boron, and fluorine. In addition, one or more elements of molybdenum (Mo), indium (In), and tin (Sn) may be contained in the chromium-containing material for forming the light-shielding film. By inclusion of one or more elements of molybdenum, indium, and tin, the etching rate for the mixed gas of a chlorine-based gas and oxygen gas can be further increased.

Note that the mask blank of the present disclosure is not limited to the mask blank illustrated in FIG. 1, and another film (etching stopper film) may be interposed between the phase shift film 2 and the light-shielding film 3. In this case, the etching stopper film is preferably made of the above-described chromium-containing material, and the light-shielding film 3 is preferably made of a silicon-containing material.

The silicon-containing material for forming the light-shielding film 3 may contain a transition metal or may contain a metal element other than the transition metal. This is because a pattern formed on the light-shielding film 3 is basically a light-shielding band pattern in an outer peripheral region, an integrated irradiation amount of ArF exposure light is smaller than that in a transfer pattern region, a fine pattern is rarely formed in the outer peripheral region, and a substantial problem hardly occurs even when ArF light resistance is low. In addition, this is because by inclusion of a transition metal in the light-shielding film 3, light-shielding performance is largely improved as compared with a case where a transition metal is not contained, and the thickness of the light-shielding film 3 can be reduced. The transition metal contained in the light-shielding film 3 is, for example, any one metal of molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), niobium (Nb), palladium (Pd), and the like, or an alloy of these metals.

In the present embodiment, the hard mask film 4 layered on the light-shielding film 3 is made of a material having etching selectivity to an etching gas used when the light-shielding film 3 is etched. As a result, as described below, the film thickness of a resist film can be significantly reduced as compared with a case where the resist film is directly used as a mask of the light-shielding film 3.

Since the light-shielding film 3 needs to have a sufficient light-shielding function while securing a predetermined optical density, there is a limit to reduction of the thickness of the light-shielding film 3. Meanwhile, it is sufficient that the hard mask film 4 has a film thickness enough to function as an etching mask until dry etching for forming a pattern on the light-shielding film 3 immediately below the hard mask film 4 is finished, and basically, the hard mask film 4 is not limited in optical characteristics. Therefore, the thickness of the hard mask film 4 can be significantly reduced as compared with the thickness of the light-shielding film 3. In addition, since it is sufficient that a resist film of an organic material has a film thickness enough to function as an etching mask until dry etching for forming a pattern on the hard mask film 4 is finished, the film thickness of the resist film can be significantly reduced as compared with a case where the resist film is directly used as a mask of the light-shielding film 3. Since the resist film can be thinned as described above, resist resolution can be improved, and collapse of a pattern to be formed can be prevented. As described above, the hard mask film 4 layered on the light-shielding film 3 is preferably made of the above-described material, but the present disclosure is not limited to this embodiment. In the mask blank 100, a resist pattern may be directly formed on the light-shielding film 3 without forming the hard mask film 4, and the light-shielding film 3 may be directly etched using the resist pattern as a mask.

In a case where the light-shielding film 3 is made of a chromium-containing material, the hard mask film 4 is preferably made of the above-described silicon-containing material. Here, since the hard mask film 4 in this case tends to have low adhesion to a resist film of an organic material, it is preferable to perform a hexamethyldisilazane (HMDS) treatment on a surface of the hard mask film 4 to improve adhesion of the surface. Note that the hard mask film 4 in this case is more preferably made of SiO₂, SiN, SiON, or the like.

In addition to the above material, a tantalum-containing material is also applicable as the material of the hard mask film 4 in a case where the light-shielding film 3 is made of a chromium-containing material. Examples of the tantalum-containing material in this case include a tantalum metal, a material containing tantalum and one or more elements selected from nitrogen, oxygen, boron, and carbon, and the like. Examples of the material include Ta, TaN, TaO, TaON, TaBN, TaBO, TaBON, TaCN, TaCO, TaCON, TaBCN, TaBOCN, and the like.

In a case where the light-shielding film 3 is made of a silicon-containing material, the hard mask film 4 is preferably made of the above-described chromium-containing material.

In the mask blank 100, a resist film of an organic material is preferably formed with a film thickness of 100 nm or less in contact with a surface of the hard mask film 4. In a case of a fine pattern corresponding to a DRAM hp 32 nm generation, a sub-resolution assist feature (SRAF) having a line width of 40 nm may be formed in a transfer pattern (phase shift pattern) to be formed on the hard mask film 4. Even in this case, since a cross-sectional aspect ratio of the resist pattern is as low as 1:2.5, it is possible to suppress collapse and detachment of the resist pattern during development, rinsing, and the like of the resist film. Note that when the film thickness of the resist film is 80 nm or less, collapse and detachment of the resist pattern are further suppressed, which is more preferable.

### [Phase Shift Mask and Manufacture Thereof]

The phase shift mask 200 of the present embodiment is characterized in that a transfer pattern (phase shift pattern) is formed on the phase shift film 2 of the mask blank 100, and a light-shielding band pattern is formed on the light-shielding film 3. In a case of a configuration in which the hard mask film 4 is formed in the mask blank 100, the hard mask film 4 is removed in a course of manufacturing the phase shift mask 200.

A method of manufacturing a phase shift mask according to the present disclosure uses the above-described mask blank 100, and is characterized by including: a step of forming a transfer pattern on the light-shielding film 3 by dry etching; a step of forming a transfer pattern on the phase shift film 2 by dry etching using the light-shielding film 3 having a transfer pattern as a mask; and a step of forming a light-shielding band pattern on the light-shielding film 3 by dry etching using a resist film (second resist pattern 6b) having a light-shielding band pattern as a mask. Hereinafter, a method of manufacturing the phase shift mask 200 of the present disclosure will be described according to the manufacturing process illustrated in FIGS. 2A-2G. Note that here, a method of manufacturing the phase shift mask 200 using the mask blank 100 in which the hard mask film 4 is layered on the light-shielding film 3 will be described. In addition, a case where a chromium-containing material is applied to the light-shielding film 3 and a silicon-containing material is applied to the hard mask film 4 will be described.

First, a resist film is formed by a spin coating method in contact with the hard mask film 4 in the mask blank 100. Next, a first pattern that is a transfer pattern (phase shift pattern) to be formed on the phase shift film 2 is drawn by exposure with an electron beam on the resist film, and a predetermined treatment such as a development treatment is further performed to form a first resist pattern 5a having the phase shift pattern (refer to FIG. 2A). Subsequently, dry etching using a fluorine-based gas is performed using the first resist pattern 5a as a mask to form a first pattern (hard mask pattern 4a) on the hard mask film 4 (refer to FIG. 2B).

Next, the first resist pattern 5a is removed, and then dry etching using a mixed gas of a chlorine-based gas and oxygen gas is performed using the hard mask pattern 4a as a mask to form a first pattern (light-shielding pattern 3a) on the light-shielding film 3 (refer to FIG. 2C). Subsequently, dry etching with a fluorine-based gas is performed using the light-shielding pattern 3a as a mask to form a first pattern (phase shift pattern 2a) on the phase shift film 2, and at the same time, the hard mask pattern 4a is removed (refer to FIG. 2D).

Next, a resist film is formed on the mask blank 100 by a spin coating method. Thereafter, a second pattern that is a pattern (light-shielding pattern) to be formed on the light-shielding film 3 is drawn by exposure with an electron beam on the resist film, and a predetermined treatment such as a development treatment is further performed to form a second resist pattern 6b having the light-shielding pattern (refer to FIG. 2E). Here, since the second pattern is a relatively large pattern, exposure drawing using a laser beam by a laser drawing apparatus having a high throughput can be performed, instead of exposure drawing using an electron beam.

Subsequently, dry etching with a mixed gas of a chlorine-based gas and oxygen gas is performed using the second resist pattern 6b as a mask to form a second pattern (light-shielding pattern 3b) on the light-shielding film 3 (refer to FIG. 2F). Furthermore, the second resist pattern 6b is removed, and then a predetermined treatment such as cleaning is performed to obtain the phase shift mask 200 (see FIG. 2G).

The chlorine-based gas used in the above-described dry etching is not particularly limited as long as chlorine (Cl) is contained. Examples thereof include Cl₂, SiCl₂, CHCl₃, CH₂Cl₂, BCl₃ and the like. The fluorine-based gas used in the above-described dry etching is not particularly limited as long as fluorine (F) is contained. Examples thereof include CHF₃, CF₄, C₂F₆, C₄F₈, SF₆, and the like. In particular, since a fluorine-based gas not containing C has a relatively low etching rate with respect to a glass substrate, damage to the glass substrate can be further reduced.

The phase shift mask 200 of the present disclosure is manufactured using the above-described mask blank 100. Therefore, in the phase shift film (phase shift pattern) on which a transfer pattern is formed, a transmittance to ArF exposure light is 1% or more, and a phase difference between exposure light that has passed through the phase shift pattern and exposure light that has passed through air by the same distance as the thickness of the phase shift pattern falls within a range of 150 degrees or more and 210 degrees. As a result, a high phase shift effect can be exhibited. In addition, at the time of EB defect correction for a black defect found in a mask inspection performed in a course of the phase shift mask 200 manufacturing process, an etching end point can be relatively easily detected. In addition, before and after irradiation with ArF exposure light, a change amount of a pattern line width of the phase shift pattern can be suppressed within an allowable range, and required light resistance to exposure light of an ArF excimer laser can be satisfied.

### [Manufacture of Semiconductor Device]

A method of manufacturing a semiconductor device according to the present disclosure is characterized in that a transfer pattern is transferred by exposure onto a resist film on a semiconductor substrate using the above-described phase shift mask 200 or a phase shift mask 200 manufactured using the above-described mask blank 100. Since the phase shift mask 200 of the present disclosure exhibits a high phase shift effect, when exposure transfer is performed onto a resist film on a semiconductor device using the phase shift mask 200 of the present disclosure, a pattern can be formed on the resist film on the semiconductor device with accuracy sufficiently satisfying design specifications. In addition, even when exposure transfer is performed onto a resist film on a semiconductor device using a phase shift mask in which a black defect portion is corrected by EB defect correction in a course of manufacturing the phase shift mask, it is possible to prevent occurrence of transfer failure in the resist film on the semiconductor device corresponding to a pattern portion where the black defect of the phase shift mask was present. Therefore, when a film to be processed is dry-etched using this resist pattern as a mask to form a circuit pattern, it is possible to form a circuit pattern with high accuracy and high yield without wiring short circuit or disconnection due to insufficient accuracy or transfer failure.

### EXAMPLES

Hereinafter, the embodiment of the present disclosure will be described more specifically with reference to Examples.

### Example 1

### [Manufacture of Mask Blank]

A transparent substrate 1 made of synthetic quartz glass and having main surfaces dimension of about 152 mm× about 152 mm and a thickness of about 6.35 mm was prepared. In the transparent substrate 1, end surfaces and main surfaces had been polished so as to have a predetermined surface roughness or less (0.2 nm or less in root mean square roughness Rq), and then subjected to a predetermined cleaning treatment and a predetermined drying treatment.

Next, the transparent substrate 1 was disposed in a single-wafer type DC sputtering apparatus, and a phase shift film 2 made of molybdenum, silicon, and nitrogen was formed on the transparent substrate 1 with a thickness of 69 nm by reactive sputtering (DC sputtering) using a mixed target of molybdenum (Mo) and silicon (Si) (Mo:Si=8 atom %: 92 atom %) and using a mixed gas of argon (Ar), nitrogen (N₂), and helium (He) as a sputtering gas.

Next, the transparent substrate 1 on which the phase shift film 2 was formed was subjected to a heat treatment for reducing a film stress of the phase shift film 2 and for forming an oxidized layer on a surface layer. Specifically, a heating treatment was performed using a heating furnace (electric furnace) at a heating temperature of 450° C. and a heating time of one hour in air. A product obtained by forming a phase shift film 2 on a main surface of another transparent substrate 1 under the same conditions and subjecting the phase shift film 2 to a heat treatment was prepared. Using a phase shift amount measurement device (MPM193 manufactured by Lasertec Corporation), a transmittance and a phase difference of the phase shift film 2 with respect to light having a wavelength of 193 nm were measured. As a result, the transmittance and the phase difference were 6.1% and 177 degrees, respectively. When an optical characteristic of the phase shift film 2 was measured using a spectroscopic ellipsometer (M-2000D manufactured by J.A. Woollam Company), a refractive index n and an extinction coefficient k with respect to light having a wavelength of 193 nm were 2.48 and 0.61, respectively.

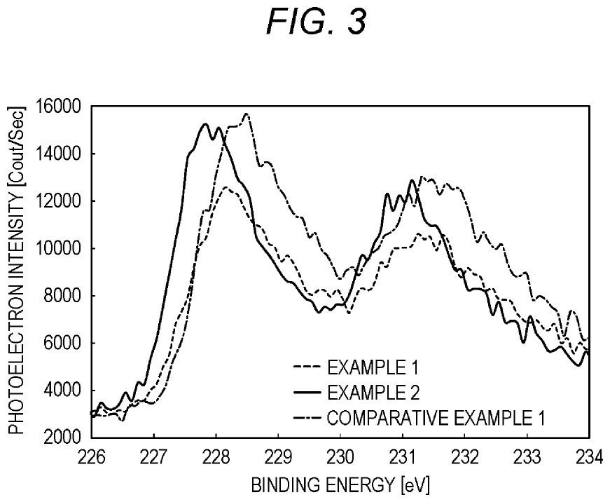

A product obtained by forming a phase shift film 2 on another transparent substrate 1 was prepared in the same procedure as that described above. A film composition of the phase shift film 2 was measured by X-ray Photoelectron Spectroscopy (XPS). The measurement result was corrected (calibrated) so as to correspond to a Rutherford Backscattering Spectrometry (RBS) measurement result. As a result, as for the composition of the phase shift film 2 in a portion excluding the neighboring region and the surface layer region, the content of Mo was 3.0 atom %, the content of Si was 49.8 atom %, the content of N was 47.2 atom %, and the content of O was 0.0 atom %. Therefore, a [(N+O)/Mo ratio] of the phase shift film 2 was 15.54, which satisfied a range of 12 or more and 19 or less. An [O/Mo ratio] of the phase shift film 2 was 0.0, which satisfied a range of less than 5. A [Mo/(Mo+Si) ratio] of the phase shift film 2 was 0.0575, which satisfied a range of 0.04 or more and 0.07 or less. As can be understood from FIG. 3, a ratio [Ip1/Ip2 ratio] of a photoelectron intensity of a maximum peak [Ip1] in a range where binding energy of a Mo3d narrow spectrum is 226 eV or more and 229 eV or less to a photoelectron intensity of a maximum peak [Ip2] in a range where the binding energy of the Mo3d narrow spectrum is 230 eV or more and 233 eV or less in the internal region of the phase shift film 2 was 1.185, which satisfied a range of less than 1.2.

Next, the transparent substrate 1 on which the phase shift film 2 was formed was disposed in a single-wafer type DC sputtering apparatus. Reactive sputtering (DC sputtering) was performed using a chromium (Cr) target and using a mixed gas of argon (Ar), carbon dioxide (CO₂), nitrogen (N₂), and helium (He) as a sputtering gas to form a lowermost layer of the light-shielding film 3 made of CrOCN on the phase shift film 2 with a thickness of 16 nm. Next, reactive sputtering (DC sputtering) was performed using the same chromium (Cr) target and using a mixed gas of argon (Ar), carbon dioxide (CO₂), nitrogen (N₂), and helium (He) as a sputtering gas to form a lower layer of the light-shielding film 3 made of CrOCN on the lowermost layer of the light-shielding film 3 with a thickness of 41 nm.

Next, reactive sputtering (DC sputtering) was performed using the same chromium (Cr) target and using a mixed gas of argon (Ar) and nitrogen (N₂) as a sputtering gas to form an upper layer of the light-shielding film 3 made of CrN on the lower layer of the light-shielding film 3 with a thickness of 6 nm. By the above method, the light-shielding film 3 made of a chromium-based material and having a three-layer structure of the lowermost layer made of CrOCN, the lower layer made of CrOCN, and the upper layer made of CrN in order from the phase shift film 2 side was formed with a total film thickness of 63 nm. Note that an optical density (OD) of the stack having the phase shift film 2 and the light-shielding film 3 at a wavelength of 193 nm was measured and found to be 3.0 or more.

Furthermore, the transparent substrate 1 on which the phase shift film 2 and the light-shielding film 3 were layered was disposed in a single-wafer type RF sputtering apparatus. RF sputtering was performed using a silicon dioxide (SiO₂) target and using an argon (Ar) gas as a sputtering gas to form a hard mask film 4 made of silicon and oxygen with a thickness of 5 nm on the light-shielding film 3. By the above method, a mask blank 100 having a structure in which the phase shift film 2, the light-shielding film 3, and the hard mask film 4 were layered on the transparent substrate 1 was manufactured.

### [Manufacture of Phase Shift Mask]

Next, using the mask blank 100 of Example 1, a phase shift mask 200 of Example 1 was manufactured in the following procedure. First, a surface of the hard mask film 4 was subjected to an HMDS treatment. Subsequently, a resist film made of a chemically amplified resist for electron beam drawing was formed with a film thickness of 80 nm in contact with the surface of the hard mask film 4 by a spin coating method. Next, a first pattern that is a phase shift pattern to be formed on the phase shift film 2 was drawn on the resist film with an electron beam. A predetermined development treatment was performed to form a first resist pattern 5a having a first pattern (refer to FIG. 2A). Note that, at this time, a programmed defect was added to the first pattern drawn with an electron beam, in addition to a phase shift pattern to be originally formed, such that a black defect was formed in the phase shift film 2.

Next, dry etching using a CF₄ gas was performed using the first resist pattern 5a as a mask to form a first pattern (hard mask pattern 4a) on the hard mask film 4 (refer to FIG. 2B).

Next, the first resist pattern 5a was removed with ashing, a stripping solution, or the like. Subsequently, dry etching using a mixed gas of chlorine and oxygen (gas flow ratio Cl₂:O₂=15:1) was performed using the hard mask pattern 4a as a mask to form a first pattern (light-shielding pattern 3a) on the light-shielding film 3 (refer to FIG. 2C).

Next, dry etching using a fluorine-based gas (SF₆+He) was performed using the light-shielding pattern 3a as a mask to form a first pattern (phase shift pattern 2a) on the phase shift film 2, and at the same time, the hard mask pattern 4a was removed (refer to FIG. 2D).

Next, a resist film made of a chemically amplified resist for electron beam drawing was formed on the light-shielding pattern 3a with a film thickness of 150 nm by a spin coating method. Next, a second pattern that is a pattern (light-shielding pattern) to be formed on the light-shielding film 3 was drawn by exposure on the resist film. A predetermined treatment such as a development treatment was further performed to form a second resist pattern 6b having the light-shielding pattern (refer to FIG. 2E). Subsequently, dry etching using a mixed gas of chlorine and oxygen (gas flow ratio Cl₂:O₂=4:1) was performed using the second resist pattern 6b as a mask to form a second pattern (light-shielding pattern 3b) on the light-shielding film 3 (refer to FIG. 2F). Furthermore, the second resist pattern 6b was removed, and then a predetermined treatment such as cleaning was performed to obtain a phase shift mask 200 (see FIG. 2G).

When the mask pattern of the manufactured halftone phase shift mask 200 of Example 1 was inspected with a mask inspection apparatus, a black defect was confirmed in the phase shift pattern 2a where the programmed defect had been added. When the black defect portion was subjected to EB defect correction with an electron beam and a XeF₂ gas using a MeRIT MG45 electron beam mask repair tool manufactured by Carl Zeiss, etching of a surface of the transparent substrate 1 could be minimized, and correction with favorable accuracy could be performed within a required time.

A product obtained by forming a phase shift pattern 2a having a line width of about 200 nm on the same phase shift film 2 as that of Example 1 formed on another transparent substrate 1 was prepared in the same procedure as that described above, and resistance to ArF excimer laser irradiation was examined. Specifically, the phase shift pattern 2a was continuously irradiated with an ArF excimer laser (wavelength: 193 nm) having a pulse frequency of 300 Hz and pulse energy of 16 J/cm²/pulse so as to have an integrated irradiation amount of 10 kJ/cm². Then, a ratio Δd of a change amount of the phase shift pattern 2a before and after ArF irradiation was calculated by observation with a Critical Dimension-Scanning Electron Microscope (CD-SEM). As a result, the ratio Δd fell within a range of 4% or less, and had ArF light resistance within an allowable range.

The halftone phase shift mask 200 of Example 1 after EB defect correction was subjected to simulation of a transfer image at the time of exposure transfer onto a resist film on a semiconductor device with exposure light having a wavelength of 193 nm using AIMS 193 (manufactured by Carl Zeiss AG). Verification of an exposure transfer image of this simulation indicated that design specifications were sufficiently satisfied. In addition, a transfer image in a portion subjected to EB defect correction was not inferior to a transfer image in the other region. From this result, it can be said that a circuit pattern finally formed on the semiconductor device can be formed with high accuracy even when the phase shift mask of Example 1 after EB defect correction is set on a mask stage of an exposure apparatus and exposure transfer is performed onto the resist film on the semiconductor device.

### Example 2

### [Manufacture of Mask Blank]

A transparent substrate 1 was prepared in the same procedure as that in Example 1. Next, the transparent substrate 1 was disposed in a single-wafer type DC sputtering apparatus. A phase shift film 2 made of molybdenum, silicon, nitrogen, and oxygen was formed on the transparent substrate 1 with a thickness of 70 nm by reactive sputtering (DC sputtering) using a mixed target of molybdenum (Mo) and silicon (Si) (Mo:Si=8 atom %: 92 atom %) and using a mixed gas of argon (Ar), nitrogen (N₂), oxygen (O₂), and helium (He) as a sputtering gas.

Next, the transparent substrate 1 on which the phase shift film 2 was formed was subjected to a heat treatment for reducing a film stress of the phase shift film 2 and for forming an oxidized layer on a surface layer. Specifically, a heating treatment was performed using a heating furnace (electric furnace) at a heating temperature of 450° C. and a heating time of 1.5 hours in air. A product obtained by forming a phase shift film 2 on a main surface of another transparent substrate 1 under the same conditions and subjecting the phase shift film 2 to a heat treatment was prepared. Using a phase shift amount measurement device (MPM193 manufactured by Lasertec Corporation), a transmittance and a phase difference of the phase shift film 2 with respect to light having a wavelength of 193 nm were measured. As a result, the transmittance and the phase difference were 6.1% and 177 degrees, respectively. When an optical characteristic of the phase shift film 2 was measured using a spectroscopic ellipsometer (M-2000D manufactured by J.A. Woollam Company), a refractive index n and an extinction coefficient k with respect to light having a wavelength of 193 nm were 2.38 and 0.57, respectively.

As in Example 1, a product obtained by forming a phase shift film 2 on another transparent substrate 1 was prepared. A film composition of the phase shift film 2 was measured by X-ray Photoelectron Spectroscopy (XPS). The measurement result was corrected (calibrated) so as to correspond to a Rutherford Backscattering Spectrometry (RBS) measurement result. As a result, as for the composition of the phase shift film 2 in a portion excluding the neighboring region and the surface layer region, the content of Mo was 3.1 atom %, the content of Si was 47.2 atom %, the content of N was 34.4 atom %, and the content of O was 15.3 atom %. Therefore, a [(N+O)/Mo ratio] of the phase shift film 2 was 15.90, which satisfied a range of 12 or more and 19 or less. In addition, an [O/Mo ratio] of the phase shift film 2 was 4.897, which satisfied a range of less than 5. In addition, a [Mo/(Mo+Si) ratio] of the phase shift film 2 was 0.0622, which satisfied a range of 0.04 or more and 0.07 or less. In addition, as can be understood from FIG. 3, a ratio [Ip1/Ip2 ratio] of a photoelectron intensity of a maximum peak [Ip1] in a range where binding energy of a Mo3d narrow spectrum is 226 eV or more and 229 eV or less to a photoelectron intensity of a maximum peak [Ip2] in a range where the binding energy of the Mo3d narrow spectrum is 230 eV or more and 233 eV or less in the internal region of the phase shift film 2 was 1.184, which satisfied a range of less than 1.2.

Next, a light-shielding film 3 and a hard mask film 4 were sequentially formed on the phase shift film 2 in the same procedure as that in Example 1. By the above method, a mask blank 100 of Example 2 having a structure in which the phase shift film 2, the light-shielding film 3, and the hard mask film 4 were layered on the transparent substrate 1 was manufactured.

### [Manufacture of Phase Shift Mask]

Next, using the mask blank 100 of Example 2, a phase shift mask 200 of Example 2 was manufactured in the same procedure as that in Example 1.

When the mask pattern of the manufactured halftone phase shift mask 200 of Example 2 was inspected with a mask inspection apparatus, a black defect was confirmed in the phase shift pattern 2a where the programmed defect had been added. When the black defect portion was subjected to EB defect correction with an electron beam and a XeF₂ gas using a MeRIT MG45 electron beam mask repair tool manufactured by Carl Zeiss, etching of a surface of the transparent substrate 1 could be minimized, and correction with favorable accuracy could be performed within a required time.

A product obtained by forming a phase shift pattern 2a having a line width of about 200 nm on the same phase shift film 2 as that of Example 2 formed on another transparent substrate 1 was prepared in the same procedure as that described above. Resistance to ArF excimer laser irradiation was examined in the same procedure as that in Example 1. As a result, a ratio Δd of a change amount in film thickness before and after ArF irradiation fell within a range of 4% or less, and had ArF light resistance within an allowable range.

The halftone phase shift mask 200 of Example 2 after EB defect correction was subjected to simulation of a transfer image at the time of exposure transfer onto a resist film on a semiconductor device with exposure light having a wavelength of 193 nm using AIMS 193 (manufactured by Carl Zeiss AG). Verification of an exposure transfer image of this simulation indicated that design specifications were sufficiently satisfied. In addition, a transfer image in a portion subjected to EB defect correction was not inferior to a transfer image in the other region. From this result, it can be said that a circuit pattern finally formed on the semiconductor device can be formed with high accuracy even when the phase shift mask of Example 2 after EB defect correction is set on a mask stage of an exposure apparatus and exposure transfer is performed onto the resist film on the semiconductor device.

### Example 3

### [Manufacture of Mask Blank]

A transparent substrate 1 was prepared in the same procedure as that in Example 1. Next, the transparent substrate 1 was disposed in a single-wafer type DC sputtering apparatus. A phase shift film 2 made of molybdenum, silicon, nitrogen, and oxygen was formed on the transparent substrate 1 with a thickness of 68 nm by reactive sputtering (DC sputtering) using a mixed target of molybdenum (Mo) and silicon (Si) (Mo:Si=8 atom %: 92 atom %) and using a mixed gas of argon (Ar), nitrogen (N₂), oxygen (O₂), and helium (He) as a sputtering gas.

Next, the transparent substrate 1 on which the phase shift film 2 was formed was subjected to a heat treatment for reducing a film stress of the phase shift film 2 and for forming an oxidized layer on a surface layer. Specifically, a heating treatment was performed using a heating furnace (electric furnace) at a heating temperature of 450° C. and a heating time of 1.5 hours in air. A product obtained by forming a phase shift film 2 on a main surface of another transparent substrate 1 under the same conditions and subjecting the phase shift film 2 to a heat treatment was prepared. Using a phase shift amount measurement device (MPM193 manufactured by Lasertec Corporation), a transmittance and a phase difference of the phase shift film 2 with respect to light having a wavelength of 193 nm were measured. As a result, the transmittance and the phase difference were 6.1% and 177 degrees, respectively. When an optical characteristic of the phase shift film 2 was measured using a spectroscopic ellipsometer (M-2000D manufactured by J.A. Woollam Company), a refractive index n and an extinction coefficient k with respect to light having a wavelength of 193 nm were 2.43 and 0.51, respectively.

As in Example 1, a product obtained by forming a phase shift film 2 on another transparent substrate 1 was prepared. A film composition of the phase shift film 2 was measured by X-ray Photoelectron Spectroscopy (XPS). The measurement result was corrected (calibrated) so as to correspond to a Rutherford Backscattering Spectrometry (RBS) measurement result. As a result, as for the composition of the phase shift film 2 in a portion excluding the neighboring region and the surface layer region, the content of Mo was 2.9 atom %, the content of Si was 48.7 atom %, the content of N was 44.0 atom %, and the content of O was 4.4 atom %. Therefore, a [(N+O)/Mo ratio] of the phase shift film 2 was 16.69, which satisfied a range of 12 or more and 19 or less. An [O/Mo ratio] of the phase shift film 2 was 1.517, which satisfied a range of less than 5. A [Mo/(Mo+Si) ratio] of the phase shift film 2 was 0.0562, which satisfied a range of 0.04 or more and 0.07 or less.

Next, a light-shielding film 3 and a hard mask film 4 were sequentially formed on the phase shift film 2 in the same procedure as that in Example 1. By the above method, a mask blank 100 of Example 3 having a structure in which the phase shift film 2, the light-shielding film 3, and the hard mask film 4 were layered on the transparent substrate 1 was manufactured.

### [Manufacture of Phase Shift Mask]

Next, using the mask blank 100 of Example 3, a phase shift mask 200 of Example 3 was manufactured by the same procedure as that in Example 1.

When the mask pattern of the manufactured halftone phase shift mask 200 of Example 3 was inspected with a mask inspection apparatus, a black defect was confirmed in the phase shift pattern 2a where the programmed defect had been added. When the black defect portion was subjected to EB defect correction with an electron beam and a XeF₂ gas using a MeRIT MG45 electron beam mask repair tool manufactured by Carl Zeiss, etching of a surface of the transparent substrate 1 could be minimized, and correction with favorable accuracy could be performed within a required time.

A product obtained by forming a phase shift pattern 2a having a line width of about 200 nm on the same phase shift film 2 as that of Example 3 formed on another transparent substrate 1 was prepared in the same procedure as that described above. Resistance to ArF excimer laser irradiation was examined in the same procedure as that in Example 1. As a result, a ratio Δd of a change amount in film thickness before and after ArF irradiation fell within a range of 4% or less, and had ArF light resistance within an allowable range.

The halftone phase shift mask 200 of Example 3 after EB defect correction was subjected to simulation of a transfer image at the time of exposure transfer onto a resist film on a semiconductor device with exposure light having a wavelength of 193 nm using AIMS 193 (manufactured by Carl Zeiss AG). Verification of an exposure transfer image of this simulation indicated that design specifications were sufficiently satisfied. In addition, a transfer image in a portion subjected to EB defect correction was not inferior to a transfer image in the other region. From this result, it can be said that a circuit pattern finally formed on the semiconductor device can be formed with high accuracy even when the phase shift mask of Example 3 after EB defect correction is set on a mask stage of an exposure apparatus and exposure transfer is performed onto the resist film on the semiconductor device.

### Comparative Example 1

### [Manufacture of Mask Blank]

A transparent substrate 1 was prepared in the same procedure as that in Example 1. Next, the transparent substrate 1 was disposed in a single-wafer type DC sputtering apparatus. A phase shift film 2 made of molybdenum, silicon, and nitrogen was formed on the transparent substrate 1 with a thickness of 69 nm by reactive sputtering (DC sputtering) using a mixed target of molybdenum (Mo) and silicon (Si) (Mo:Si=12 atom %: 88 atom %) and using a mixed gas of argon (Ar), nitrogen (N₂), and helium (He) as a sputtering gas.

Next, the transparent substrate 1 on which the phase shift film 2 was formed was subjected to a heat treatment for reducing a film stress of the phase shift film 2 and for forming an oxidized layer on a surface layer. Specifically, a heating treatment was performed using a heating furnace (electric furnace) at a heating temperature of 450° C. and a heating time of 1.5 hours in air. A product obtained by forming a phase shift film 2 on a main surface of another transparent substrate 1 under the same conditions and subjecting the phase shift film 2 to a heat treatment was prepared. Using a phase shift amount measurement device (MPM193 manufactured by Lasertec Corporation), a transmittance and a phase difference of the phase shift film 2 with respect to light having a wavelength of 193 nm were measured. As a result, the transmittance and the phase difference were 6.1% and 177 degrees, respectively. When an optical characteristic of the phase shift film 2 was measured using a spectroscopic ellipsometer (M-2000D manufactured by J.A. Woollam Company), a refractive index n and an extinction coefficient k with respect to light having a wavelength of 193 nm were 2.43 and 0.60, respectively.

As in Example 1, a product obtained by forming a phase shift film 2 on another transparent substrate 1 was prepared. A film composition of the phase shift film 2 was measured by X-ray Photoelectron Spectroscopy (XPS). The measurement result was corrected (calibrated) so as to correspond to a Rutherford Backscattering Spectrometry (RBS) measurement result. As a result, as for the composition of the phase shift film 2 in a portion excluding the neighboring region and the surface layer region, the content of Mo was 4.0 atom %, the content of Si was 48.9 atom %, the content of N was 47.1 atom %, and the content of O was 0.0 atom %. Therefore, a [(N+O)/Mo ratio] of the phase shift film 2 was 11.76, which did not satisfy a range of 12 or more and 19 or less. An [O/Mo ratio] of the phase shift film 2 was 0.000, which satisfied a range of less than 5. A [Mo/(Mo+Si) ratio] of the phase shift film 2 was 0.0756, which did not satisfy a range of 0.04 or more and 0.07 or less. As can be understood from FIG. 3, a ratio [Ip1/Ip2 ratio] of a photoelectron intensity of a maximum peak [Ip1] in a range where binding energy of a Mo3d narrow spectrum is 226 eV or more and 229 eV or less to a photoelectron intensity of a maximum peak [Ip2] in a range where the binding energy of the Mo3d narrow spectrum is 230 eV or more and 233 eV or less in the internal region of the phase shift film 2 was 1.207, which did not satisfy a range of less than 1.2.

Next, a light-shielding film 3 and a hard mask film 4 were sequentially formed on the phase shift film 2 in the same procedure as that in Example 1. By the above method, a mask blank 100 of Comparative Example 1 having a structure in which the phase shift film 2, the light-shielding film 3, and the hard mask film 4 were layered on the transparent substrate 1 was manufactured.

### [Manufacture of Phase Shift Mask]

Next, using the mask blank 100 of Comparative Example 1, a phase shift mask 200 of Comparative Example 1 was manufactured by a procedure similar to that in Example 1.

When the mask pattern of the manufactured halftone phase shift mask 200 of Comparative Example 1 was inspected with a mask inspection apparatus, a black defect was confirmed in the phase shift pattern 2a where the programmed defect had been added. When the black defect portion was subjected to EB defect correction with an electron beam and a XeF₂ gas using a MeRIT MG45 electron beam mask repair tool manufactured by Carl Zeiss, etching of a surface of the transparent substrate 1 could be minimized, and correction with favorable accuracy could be performed within a required time.

A product obtained by forming a phase shift pattern 2a having a line width of about 200 nm on the same phase shift film 2 as that of Comparative Example 1 formed on another transparent substrate 1 was prepared in the same procedure as that described above. Resistance to ArF excimer laser irradiation was examined in the same procedure as that in Example 1. As a result, a ratio Δd of a change amount in film thickness before and after ArF irradiation exceeded 4%, and did not have ArF light resistance within an allowable range.

The halftone phase shift mask 200 of Comparative Example 1 after ArF irradiation was subjected to simulation of a transfer image at the time of exposure transfer onto a resist film on a semiconductor device with exposure light having a wavelength of 193 nm using AIMS 193 (manufactured by Carl Zeiss AG). Verification of an exposure transfer image of this simulation indicated that design specifications were not satisfied and that the exposure transfer image was at a level where transfer failure occurred. From this result, when the phase shift mask 200 of Comparative Example 1 after ArF irradiation is set on a mask stage of an exposure apparatus and exposure transfer is performed onto a resist film on a semiconductor device, it is expected that disconnection or short circuit of a circuit pattern finally formed on the semiconductor device will occur in the circuit pattern.

### Comparative Example 2

### [Manufacture of Mask Blank]

A transparent substrate 1 was prepared in the same procedure as that in Example 1. Next, the transparent substrate 1 was disposed in a single-wafer type DC sputtering apparatus. A phase shift film 2 made of molybdenum, silicon, and nitrogen was formed on the transparent substrate 1 with a thickness of 62 nm by reactive sputtering (DC sputtering) using a mixed target of molybdenum (Mo) and silicon (Si) (Mo:Si=4 atom %: 96 atom %) and using a mixed gas of argon (Ar), nitrogen (N₂), and helium (He) as a sputtering gas.

Next, the transparent substrate 1 on which the phase shift film 2 was formed was subjected to a heat treatment for reducing a film stress of the phase shift film 2 and for forming an oxidized layer on a surface layer. Specifically, a heating treatment was performed using a heating furnace (electric furnace) at a heating temperature of 450° C. and a heating time of 1.5 hours in air. A product obtained by forming a phase shift film 2 on a main surface of another transparent substrate 1 under the same conditions and subjecting the phase shift film 2 to a heat treatment was prepared. Using a phase shift amount measurement device (MPM193 manufactured by Lasertec Corporation), a transmittance and a phase difference of the phase shift film 2 with respect to light having a wavelength of 193 nm were measured. As a result, the transmittance and the phase difference were 6.1% and 177 degrees, respectively. When an optical characteristic of the phase shift film 2 was measured using a spectroscopic ellipsometer (M-2000D manufactured by J.A. Woollam Company), a refractive index n and an extinction coefficient k with respect to light having a wavelength of 193 nm were 2.58 and 0.66, respectively.

As in Example 1, a product obtained by forming a phase shift film 2 on another transparent substrate 1 was prepared. A film composition of the phase shift film 2 was measured by X-ray Photoelectron Spectroscopy (XPS). The measurement result was corrected (calibrated) so as to correspond to a Rutherford Backscattering Spectrometry (RBS) measurement result. As a result, as for the composition of the phase shift film 2 in a portion excluding the neighboring region and the surface layer region, the content of Mo was 1.6 atom %, the content of Si was 51.9 atom %, the content of N was 46.5 atom %, and the content of O was 0.0 atom %. Therefore, a [(N+O)/Mo ratio] of the phase shift film 2 was 29.06, which did not satisfy a range of 12 or more and 19 or less. An [O/Mo ratio] of the phase shift film 2 was 0.000, which satisfied a range of less than 5. A [Mo/(Mo+Si) ratio] of the phase shift film 2 was 0.0299, which did not satisfy a range of 0.04 or more and 0.07 or less.

Next, a light-shielding film 3 and a hard mask film 4 were sequentially formed on the phase shift film 2 in the same procedure as that in Example 1. By the above method, a mask blank 100 of Comparative Example 2 having a structure in which the phase shift film 2, the light-shielding film 3, and the hard mask film 4 were layered on the transparent substrate 1 was manufactured.

### [Manufacture of Phase Shift Mask]

Next, using the mask blank 100 of Comparative Example 2, a phase shift mask 200 of Comparative Example 2 was manufactured by the same method as that in Example 1.

When the mask pattern of the manufactured halftone phase shift mask 200 of Comparative Example 2 was inspected with a mask inspection apparatus, a black defect was confirmed in the phase shift pattern 2a where the programmed defect had been added. When the black defect portion was subjected to EB defect correction with an electron beam and a XeF₂ gas using a MeRIT MG45 electron beam mask repair tool manufactured by Carl Zeiss, time for the EB defect correction largely exceeded a required time, and accuracy of correction was not allowable.

The halftone phase shift mask 200 of Comparative Example 2 after EB defect correction was subjected to simulation of a transfer image at the time of exposure transfer onto a resist film on a semiconductor device with exposure light having a wavelength of 193 nm using AIMS 193 (manufactured by Carl Zeiss AG). Verification of an exposure transfer image of this simulation indicated that design specifications were sufficiently satisfied except for a portion where EB defect correction was performed. However, a transfer image in a portion subjected to EB defect correction was at a level at which transfer failure occurred due to an influence of etching to the transparent substrate 1 or the like. From this result, when the phase shift mask 200 of Comparative Example 2 after EB defect correction is set on a mask stage of an exposure apparatus and exposure transfer is performed onto a resist film on a semiconductor device, it is expected that disconnection or short circuit of a circuit pattern finally formed on the semiconductor device will occur in the circuit pattern.

### REFERENCE SIGNS LIST

1 Transparent substrate
2 Phase shift film
2a Phase shift pattern
3 Light-shielding film
3a, 3b Light-shielding pattern
4 Hard mask film
4a Hard mask pattern
5a First resist pattern
6b Second resist pattern
100 Mask blank
200 Phase shift mask

1. A mask blank comprising:
a transparent substrate; and
a phase shift film on a surface of the transparent substrate, wherein
the phase shift film comprises a transition metal, silicon, and nitrogen, and
a ratio of a total content of nitrogen and oxygen to a content of the transition metal is 12 or more and 19 or less in an internal region of the phase shift film, wherein the internal region excludes a neighboring region of the phase shift film, which is located adjacent to the surface of the transparent substrate, and a surface layer region of the phase shift film which is located opposite the surface of the transparent substrate.

2. The mask blank according to claim 1, wherein the phase shift film has a total content of the transition metal, silicon, nitrogen, and oxygen of 97 atom % or more.

3. The mask blank according to claim 1, wherein the surface layer region extends 5 nm from a first surface of the phase shift film which is opposite to a second surface of the phase shift film adjacent to the transparent substrate.

4. The mask blank according to claim 1, wherein the neighboring region extends 5 nm from an interface with the surface of the transparent substrate.

5. The mask blank according to claim 1, wherein the surface layer region has a larger oxygen content than the internal region.

6. The mask blank according to claim 1, wherein a ratio of a content of oxygen to a content of the transition metal in the internal region is less than 5.0.

7. The mask blank according to claim 1, wherein a ratio of a content of the transition metal to a total content of the transition metal and silicon in the internal region is 0.04 or more and 0.07 or less.

8. The mask blank according to claim 1, wherein
the transition metal is molybdenum, and
when a Mo3d narrow spectrum in the internal region is acquired by performing analysis by X-ray photoelectron spectroscopy on the internal region, a ratio of a maximum peak in a range where binding energy of the Mo3d narrow spectrum is 226 eV or more and 229 eV or less to a maximum peak in a range where the binding energy of the Mo3d narrow spectrum is 230 eV or more and 233 eV or less is less than 1.2.

9. The mask blank according to claim 1, wherein the phase shift film transmits exposure light of an ArF excimer laser with a transmittance of 1% or more, and generates a phase difference of 150 degrees or more and 210 degrees or less with respect to the exposure light.

10. The mask blank according to claim 1, comprising a light-shielding film on the first surface of the phase shift film.

11. (canceled)

12. (canceled)

13. A phase shift mask comprising:
a transparent substrate;
a phase shift film on a surface of the transparent substrate, wherein
the phase shift film comprises a transition metal, silicon, and nitrogen, and wherein a ratio of a total content of nitrogen and oxygen to a content of the transition metal is 12 or more and 19 or less in an internal region of the phase shift film, wherein the internal region excludes a neighboring region of the phase shift film, which is located adjacent to the surface of the transparent substrate, and a surface layer region of the phase shift film which is located opposite the surface of the transparent substrate; and
a light-shielding film on a surface of the surface layer region of the phase shift film.

14. The phase shift mask according to claim 13, wherein the phase shift film has a total content of the transition metal, silicon, nitrogen, and oxygen of 97 atom % or more.

15. The phase shift mask according to claim 13, wherein the surface layer region extends 5 nm from a first surface of the phase shift film which is opposite to a second surface of the phase shift film adjacent to the transparent substrate.

16. The phase shift mask according to claim 13, wherein the neighboring region extends 5 nm from an interface with the surface of the transparent substrate.

17. The phase shift mask according to claim 13, wherein the surface layer region has a larger oxygen content than the internal region.

18. The phase shift mask according to claim 13, wherein a ratio of a content of oxygen to a content of the transition metal in the internal region is less than 5.0.

19. The phase shift mask according to claim 13, wherein a ratio of a content of the transition metal to a total content of the transition metal and silicon in the internal region is 0.04 or more and 0.07 or less.

20. The phase shift mask according to claim 13, wherein
the transition metal is molybdenum, and
when a Mo3d narrow spectrum in the internal region is acquired by performing analysis by X-ray photoelectron spectroscopy on the internal region, a ratio of a maximum peak in a range where binding energy of the Mo3d narrow spectrum is 226 eV or more and 229 eV or less to a maximum peak in a range where the binding energy of the Mo3d narrow spectrum is 230 eV or more and 233 eV or less is less than 1.2.

21. The phase shift mask according to claim 13, wherein the phase shift film transmits exposure light of an ArF excimer laser with a transmittance of 1% or more, and generates a phase difference of 150 degrees or more and 210 degrees or less with respect to the exposure light.
